(19) United States
(12) Patent Application Publication
(10) Pub. No.: US 2010/0163741 A1
(43) Pub. Date: Jul. 1, 2010

(54) RADIATION DETECTOR

(76) Inventors: Junichi Suzuki, Kyoto (JP); Toshiyuki Sato, Kyoto (JP); Hiroshi Koyama, Kyoto (JP); Kenji Sato, Kyoto (JP)

Correspondence Address: Cheng Law Group, PLLC, 1100 17th Street, N.W., Suite 503, Washington, DC, 20036, US

(21) Appl. No.: 12/601,256

(22) PCT Filed: May 12, 2008
(86) PCT No.: PCT/JP2008/058731

§ 371 Date: Nov. 21, 2009

(30) Foreign Application Priority Data
May 21, 2007 (JP) 2007-134205

(51) Int. Cl. G01T 1/24

(52) U.S. Cl. 250/370.14

(57) ABSTRACT

In the radiation detector of this invention, the second common electrode is formed on the incidence surface of the seat so as to cover at least a portion of the seat and the second common electrode is connected to the first common electrode. Thus, the second common electrode is bent at the periphery of the semiconductor and the seat, and a bent portion thereof is formed sharp. The first common electrode formed along the incidence surface of the semiconductor is disposed under the sharp portion of the second electrode (i.e., opposite to the incidence surface). Consequently, the common electrode seen from a bottom (opposite to the incidence surface) has a uniform shape, which avoids occurrence of irregular concentration of the electric fields. As a result, dark current due to concentration of the electric fields may be suppressed.

### TECHNICAL FIELD

This invention relates to radiation detectors having a radiation sensitive semiconductor for generating electric charges upon incidence of radiation, for use in the medical, industrial, nuclear and other fields.

### BACKGROUND ART

Such conventional radiation (e.g. X-ray) detectors include an “indirect conversion type” detector which once generates light upon incidence of radiation (e.g. X-rays) and generates electric charges from the light, thus detecting the radiation by converting the radiation indirectly into the electric charges, and a “direct conversion type” detector which generates electric charges upon incidence of radiation, thus detecting the radiation by converting the radiation directly into the electric charges. Here, a radiation sensitive semiconductor generates the electric charges.

As shown in FIG. 13, a direct conversion type radiation detector has an active matrix substrate 51, a radiation sensitive semiconductor 52 for generating electric charges upon incidence of radiation, and a common electrode 53 for bias voltage application. The active matrix substrate 51 has a plurality of collecting electrodes (not shown) formed on a radiation incidence surface thereof, with an electric circuit (not shown) arranged for storing and reading electric charges collected by each collecting electrode. Each respective collecting electrode is set in a two-dimensional matrix array inside a radiation detection effective area SA.

The semiconductor 52 is stacked on the incidence surfaces of the collecting electrodes formed on the active matrix substrate 51, and the common electrode 53 is planarly formed and stacked on the incidence surface of the semiconductor 52. A lead wire 54 for bias voltage supply is connected to the incidence surface of the common electrode 53.

In radiation detection by the radiation detector, a bias voltage from a bias voltage source (not shown) is applied to the common electrode 53 for bias voltage application via the lead wire 54 for bias voltage supply. With the bias voltage applied, electric charges are generated b the radiation sensitive semiconductor 52 upon incidence of the radiation. The generated electric charges are temporarily collected by the collecting electrodes. The electric charges collected by the collecting electrodes are fetched as radiation detection signals from each collecting electrode by the storing and reading electric circuit including capacitors, switching elements, electrical wires, etc.

Each of the collecting electrodes in the two-dimensional matrix array corresponds to an electrode (pixel electrode) in correspondence to each pixel in a radiographic image. Fetching of radiation detection signals allows a radiographic image to be created according to a two-dimensional intensity distribution of the radiation projected to the radiation detection effective area SA.

However, the conventional radiation detector shown in FIG. 13 has a problem of performance degradation due to connecting of the lead wire 54 to the common electrode 53. That is, since a rigid metal wire such as a copper wire is used for the lead wire 54 for bias voltage supply, damage may occur to the radiation sensitive semiconductor 52 when the lead wire 54 is connected to the common electrode 53, thereby causing performance degradation such as poor voltage tolerance.

Particularly where the semiconductor 52 is amorphous selenium or a non-selenic polycrystalline semiconductor such as CdTe, CdZnTe, PbI₂, HgI₂ or TlBr, the radiation sensitive semiconductor 52 of large area and thickness may easily be formed by vacuum deposition. On the other hand, amorphous selenium and non-selenic polycrystalline semiconductor are flexible and likely to be damaged.

In order to avoid the performance degradation due to connecting of the lead wire 54 to the common electrode 53, inventors have proposed an invention as shown in FIG. 14 (see Patent Document 1, for example). As shown in FIG. 14 (corresponding to FIG. 2 of Patent Document 1), an insulating seat 55 is disposed in the incidence surface of the semiconductor 52 outside the radiation detection effective area SA. A common electrode 53 is formed to cover at least a part of the seat 55, and a lead wire 54 is connected to a portion of the incidence surface of the common electrode 53 located on the seat 55.

With such seat 55 disposed, the seat 55 may reduce a shock applied when the lead wire 54 is connected to the common electrode 53. This consequently prevents damage to the radiation sensitive semiconductor that leads to poor voltage tolerance, and avoids performance degradation such as poor voltage tolerance. The seat 55 is disposed outside the radiation detection effective area SA, thereby preventing loss of the radiation detecting function.

[Patent Document 1]

Unexamined Patent Publication No. 2005-86059 (pages 1, 2, 4 to 12, FIGS. 1, 2, 6 to 9)

### DISCLOSURE OF THE INVENTION

### Problem to be Solved by the Invention

However, where the insulating seat is disposed as in the above-mentioned Patent Document 1, the common electrode 53 is bent at the periphery of the semiconductor 52 and the seat 55 shown in FIG. 4, which leads to a tendency of formation of a sharp portion thereof. Moreover, the seat 55 is usually formed of a resin, and thus this portion is likely to have a higher dielectric constant in general.

Specifically, with the configuration shown in FIG. 14, the common electrode 53 is not formed on the semiconductor 52 at the seat 55 portion, but is formed so as to ride on the seat 55. However, in the radiation detector, a bias voltage applied to the common electrode 53 is usually a high voltage of more than several kilovolts. Thus, dark current due to concentration of electric fields in the seat 55 and the adjacent portion thereof may occur. This results from a shape of the bent portion mentioned above as a singular point in the whole structure of the common electrode 53. That is, the sharp portion is likely to be formed where the electric fields are likely to be concentrated that sandwich the semiconductor 52 and toward the collection electrodes (counter electrodes) on a TFT (thin film field-effect transistor). In addition, electrodes are formed in the seat 55 with a high dielectric constant, and this portion results in a singular point to which an irregular electric field is likely to be applied.

However, where amorphous selenium is used for the semiconductor 52 as mentioned above, it is flexible and likely to be damaged, which leads to performance degradation in connecting the lead 54 into direct contact with the common electrode 53. Therefore, it is difficult to remove the seat 55. Moreover, the seat 55 may be disposed after formation of the common electrode 53. In such a case, however, it is difficult to electrically connect the lead 54 with the common electrode 53.

This invention has been made regarding the state of the art noted above, and its object is to provide a radiation detector that can suppress dark current due to concentration of the electric fields.

### Means for Solving the Problem

This invention adopts the following configuration in order to achieve the above object. A radiation detector of this invention is a radiation detector for detecting radiation, including a radiation sensitive semiconductor for generating electric charges upon incidence of the radiation, a first common electrode for bias voltage application planarly formed so as to directly contact an incidence surface of the semiconductor, an insulating seat formed on an incidence surface of the first common electrode so as to cover a portion of the first common electrode, a second common electrode for bias voltage application formed on an incidence surface of the seat so as to cover at least a portion of the seat and connected to the first common electrode, and a lead wire for bias voltage supply connected to a portion of the incidence surface of the second electrode located on the seat, in which the first common electrode has a dimension in a predetermined range including a radiation detection effective area.

According to the radiation detector of this invention, the first common electrode (for bias voltage application) in a planar shape is formed so as to directly contact the incidence surface of the semiconductor (of the radiation sensitive type). The first common electrode has a dimension in a predetermined range including the radiation detection effective area. The insulating seat is formed on the incidence surface of the first common electrode so as to cover a portion of the first common electrode. The second common electrode (for bias voltage application) is formed on the incidence surface of the seat so as to cover at least a portion of the seat and to be connected to the first common electrode. The lead wire (for bias voltage supply) is connected to a portion of the incidence surface of the second electrode located on the seat. Where a bias voltage is to be applied to the common electrode, the bias voltage is applied to the second common electrode via the lead wire, and then applied to the first common electrode connected to the second common electrode.

The second common electrode is formed on the incidence surface of the seat so as to cover at least a portion of the seat and to be connected to the first common electrode. Thus, the second common electrode bends at the periphery of the semiconductor and the seat, and a bent portion thereof is formed sharp. The first common electrode formed along the incidence surface of the semiconductor is disposed under the sharp portion of the second electrode (i.e., opposite to the incidence surface). Consequently, the common electrode seen from a bottom (opposite to the incidence surface) has a uniform shape, which avoids occurrence of irregular concentration of the electric fields. As a result, dark current due to concentration of the electric fields may be suppressed.

In one embodiment of the foregoing invention, the second common electrode also has a dimension in the predetermined range including the above-mentioned radiation detection effective area. in another embodiment of the foregoing invention, the second common electrode is disposed on a portion on the seat outside the radiation detection effective area.

The first common electrode is sufficiently connected to the second common electrode on the seat and the perimeter thereof. Thus, as in case of a latter embodiment, the second common electrode may be disposed only on the portion on the seat outside the radiation detection effective area. Moreover, the second common electrode has a smaller area compared to that in a former embodiment. As a result, the second common electrode may be formed (for example, vapor deposited) only on the seat and a corresponding circumference portion thereof, which allows reduction of an amount of the material to be used for formation (for example, vapor deposition) of the second common electrode. Furthermore, there may be generally decreased influences of heat on the semiconductor occurring from the formation (for example, the vapor deposition).

In the foregoing invention, the second common electrode may be formed so as to cover the entire seat.

### Effects of the Invention

According to the radiation detector of this invention, the second common electrode (for bias voltage application) is formed on the incidence surface of the seat so as to cover at least a portion of the insulating seat and to be connected to the first common electrode (for bias voltage application). Thus, the second common electrode bends at the periphery of the semiconductor (of the radiation sensitive type) and the seat, and a bent portion thereof is formed sharp. The first common electrode formed along the incidence surface of the semiconductor is disposed under the sharp portion of the second electrode (i.e., opposite to the incidence surface). Consequently, the common electrode seen from a bottom (opposite to the incidence surface) has a uniform shape, which avoids occurrence of irregular concentration of the electric fields. As a result, dark current due to concentration of the electric fields may be suppressed.

### BRIEF DESCRIPTION OF THE DRAWINGS

FIG. 1 is a schematic plan view of a direct conversion type flat panel X-ray detector (FPD) in accordance with Embodiment 1;

FIG. 2 is a schematic sectional view of the flat panel X-ray detector (FPD) in accordance with Embodiment 1;

FIG. 3 is a block diagram showing an equivalent circuit of an active matrix substrate of the flat panel X-ray detector (FPD);

FIG. 4 is a schematic sectional view of the active matrix substrate of the flat panel X-ray detector (FPD);

FIGS. 5(a) to (c) are schematic sectional views each showing combinations of intermediate layers which are carder selective high resistance semiconductor layers;

FIG. 6 is a schematic plan view of a flat-panel X-ray detector (FPD) accordance with Embodiment 2;

FIG. 7 is a schematic sectional view of the flat-panel X-ray detector (FPD) in accordance with Embodiment 2;

FIG. 8 is a schematic plan view of a flat-panel X-ray detector (FPD) in accordance with Embodiment 3;

FIG. 9 is a schematic sectional view of the flat-panel X-ray detector (FPD) in accordance with Embodiment 3;

FIG. 10 is a schematic plan view of a flat-panel X-ray detector (FPD) in accordance with Embodiment 4;

FIG. 11 is a schematic sectional view of the flat-panel X-ray detector (FPD) in accordance with Embodiment 4;

FIG. 12 is a schematic plan view of a flat-panel X-ray detector (FPD) in accordance with one modification;

FIG. 13 is a schematic sectional view of a conventional radiation detector; and

FIG. 14 is a schematic sectional view of another conventional radiation detector other than that of FIG. 13.

### DESCRIPTION OF REFERENCES

2 . . . (radiation sensitive) semiconductor

3 . . . common electrode (for bias voltage application)

3a . . . first common electrode

3b . . . second common electrode

4 . . . lead wire (for bias voltage supply)

5 . . . (insulating) seat

SA . . . radiation detection effective area

### EMBODIMENTS 1

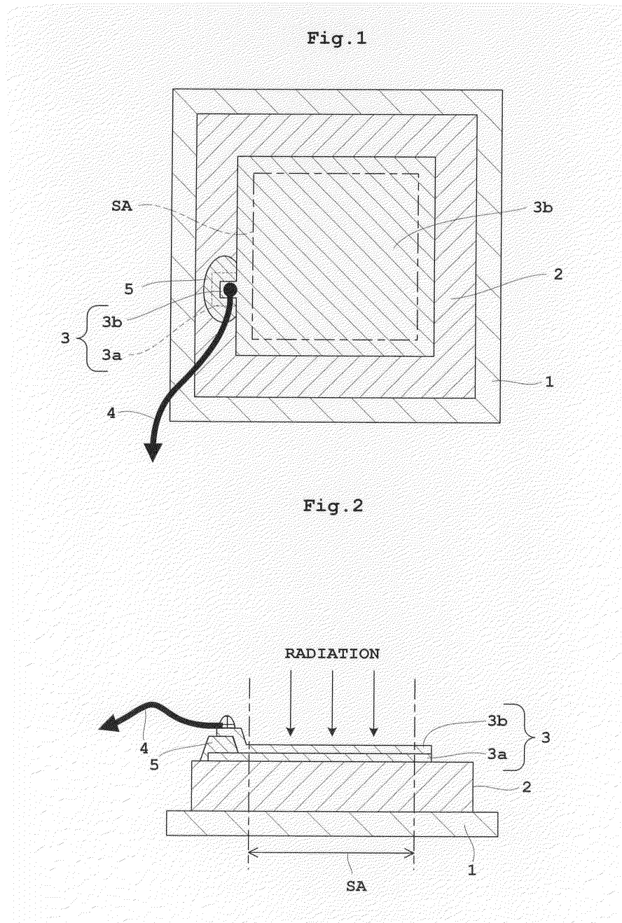

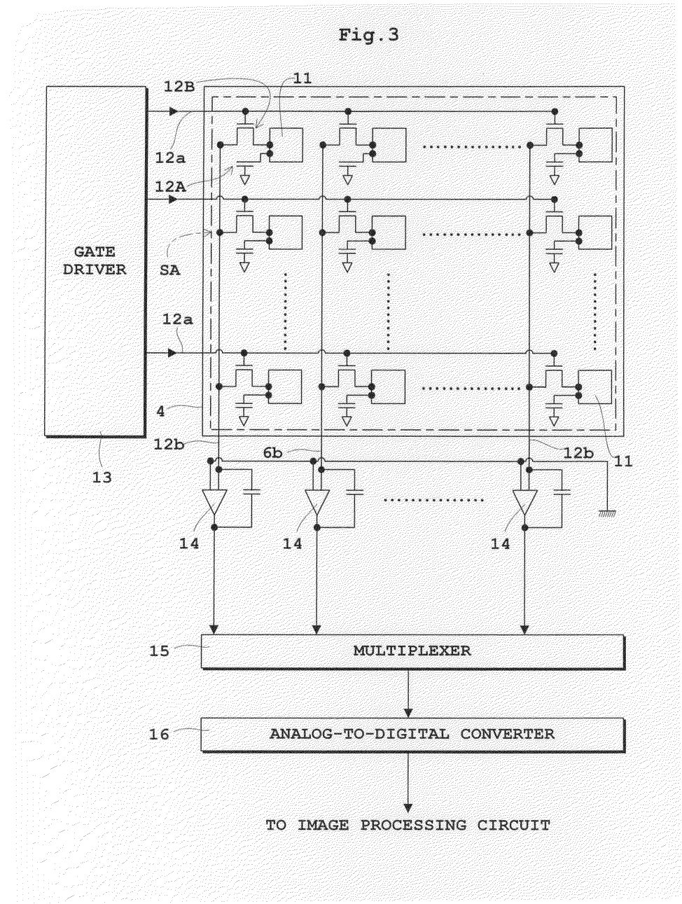

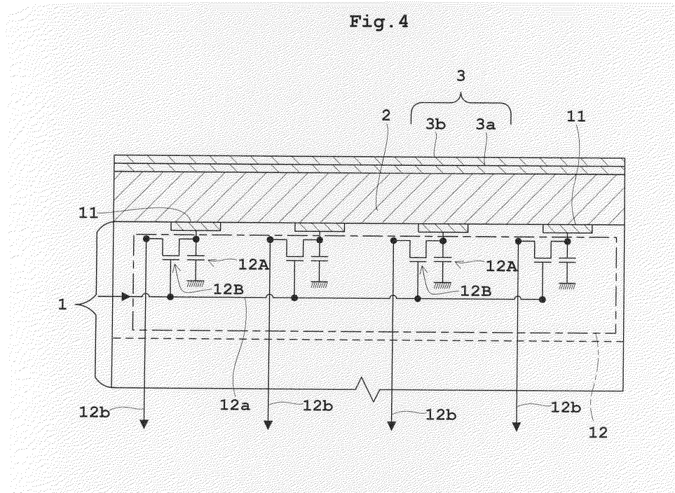

Embodiment 1 of this invention will be described hereinafter with reference to the drawings. FIG. 1 is a schematic plan view of a direct conversion type flat panel X-ray detector (hereinafter appropriately abbreviated as “FPD”) in accordance with Embodiment 1. FIG. 2 is a schematic sectional view of the flat panel X-ray detector (FPD) in accordance with Embodiment 1. FIG. 3 is a block diagram showing an equivalent circuit of an active matrix substrate of the flat panel X-ray detector (FPD). FIG. 4 is a schematic sectional view of the active matrix substrate of the flat panel X-ray detector (FPD). The flat panel X-ray detector (FPD) will be described as an example of the radiation detector in Embodiment 1 and in Embodiments 2 to 4 to follow.

As shown in FIGS. 1 and 2, the FPD in accordance with Embodiment 1 includes an active matrix substrate 1, a radiation sensitive semiconductor 2 for generating electric charges upon incidence of radiation (X-rays in Embodiments 1 to 4), and a common electrode 3 for bias voltage application. As shown in FIGS. 3 and 4, the active matrix substrate 1 has two or more collecting electrodes 11 formed on a radiation incidence surface thereof, and an electric circuit 12 for storing and reading electric charges collected by each of the collecting electrodes 11. Each of the collecting electrodes 11 is set in a two-dimensional matrix array inside a radiation detection effective area SA. The radiation sensitive semiconductor 2 corresponds to the radiation sensitive semiconductor in this invention. The common electrode 3 for bias voltage application corresponds to the first and second common electrodes for bias voltage application in this invention. The radiation detection effective area SA corresponds to the radiation detection effective area in this invention.

As shown in FIG. 1, the semiconductor 2 is stacked on the incidence surfaces of the collecting electrodes formed on the active matrix substrate 1, and the common electrode 3 is planarly formed and stacked on the incidence surface of the semiconductor 2. The lead wire 4 for bias voltage supply is connected to the incidence surface of the second common electrode 3b of the common electrode 3, which will be described hereinafter. The lead wire 4 such as a copper wire is connected to the second common electrode 3b of the common electrode 3 via conductive paste (e.g. silver paste). The lead wire 4 for bias voltage supply corresponds to the lead wire for bias voltage supply in this invention.

As shown in FIGS. 3 and 4, and as described above, the active matrix substrate 1 has the collecting electrodes 11 formed thereon, and the storing and reading electric circuit 12 arranged therein. The storing and reading electric circuit 12 includes capacitors 12A, TFTs (thin film field effect transistors) 12B acting as switching elements, gate lines 12a, and data lines 12b. One capacitor 12A and one TFT 12B are correspondingly connected to each of the collecting electrodes 11.

Further, a gate driver 13, charge-to-voltage converting amplifiers 14, a multiplexer 15, and an analog-to-digital converter 16 are arranged around and connected to the storing and reading electric circuit 12 of the active matrix substrate 1. The gate driver 13, charge-to-voltage convening amplifiers 14, multiplexer 15, and analog-to-digital converter 16 are connected via a substrate different from the active matrix substrate 1. Some or all of these gate driver 13, charge-to-voltage converting amplifiers 14, multiplexer 15, and analog-to-digital converter 16 may be built in the active matrix substrate 1.

In detecting X-rays by the FPD, a bias voltage from a bias voltage source (not shown) is applied to the common electrode 3 for bias voltage application via the lead wire 4 for bias voltage supply. With the bias voltage applied, electric charges are generated in the radiation sensitive semiconductor 2 upon incidence of the radiation (X-rays in Embodiments 1 to 4). The generated electric charges are temporarily collected by the collecting electrodes 11. The collected electric charges are fetched as radiation detection signals (X-ray detection signals in Embodiments 1 to 4) from each of the collecting electrode 11 by the storing and reading electric circuit 12.

Specifically, the electric charges collected by the collecting electrodes 11 are temporarily stored in the capacitors 12A. Then, read signals are applied successively from the gate driver 13 via the gate lines 12a to each gate of the TFTs 12B. With application of the read signals, the TFTs 12B receiving the read signals are moved, from OFF to ON. As the data lines 12b connected to the sources of the moved TFTs 12B are successively switched by the multiplexer 15, the electric charges stored in the capacitors 12A are read from the TFTs 12B via the data lines 12b. The read electric charges are amplified by the charge-to-voltage converting amplifiers 14 and transmitted by the multiplexer 15 as radiation detection signals (X-ray detection signals in Embodiments 1 to 4) from each of the collecting electrodes 11, to the analog-digital converter 16 for conversion of analog values to digital values.

Where the FPD is provided for fluoroscopic X-ray apparatus, for example, X-ray detection signals are transmitted to an image processing circuit, disposed at a subsequent stage, for image processing to output a two-dimensional fluoroscopic image, etc. Each of the collecting electrodes 11 in the two-dimensional matrix array corresponds to an electrode (pixel electrode) in correspondence to each pixel in the radiographic image (here, two-dimensional fluoroscopic X-ray image). Fetching of the radiation detection signals (X-ray detection signals in Embodiments 1 to 4) allows a radiographic image (here, two-dimensional fluoroscopic X-ray image) to be created according to a two-dimensional intensity distribution of the radiation projected to the radiation detection effective area SA. In other words, the FPD in Embodiment 1, and in Embodiments 2 to 4 to follow, is a two-dimensional array type radiation detector for detecting a two-dimensional intensity distribution of the radiation (X-rays in Embodiments 1 to 4) projected to the radiation detection effective area SA.

Next, each component of the FPD will be described in detail. As shown in FIG. 1 and FIG. 2, the common electrode 3 includes the first common electrode 3a and the second common electrode 3b. The first common electrode 3a is formed so as to directly contact the incidence surface of the semiconductor 2. The first common electrode 3a has a dimension in a predetermined range including the radiation detection effective area SA. Here in Embodiment 1, and as in Embodiment 3 to follow, the second common electrode 3b also has a dimension similar to the first common electrode 3a. That is, the second common electrode 3b also has a dimension in a predetermined range including the radiation detection effective area SA. The first common electrode 3a corresponds to the first common electrode in this invention. The second common electrode 3b corresponds to the second common electrode in this invention.

The insulating seat 5 is formed on the incidence surface of the first common electrode 3a so as to cover a portion of the first common electrode 3a. The second common electrode 3b is formed on the incidence surface of the seat 5 so as to cover at least a portion of the seat 5 and to be connected to the first common electrode 3a. That is, the second common electrode 3b is formed so as to directly contact the incidence surface of the first common electrode 3a at a portion other than the seat 5. The insulating seat 5 corresponds to the insulating seat in this invention.

The lead wire 4 is connected to a portion of the incidence surface of the second electrode 3b located on the seat 5. Where a bias voltage is to be applied to the common electrode 3, the bias voltage is applied to the second common electrode 3b via the lead wire 4, and then applied to the first common electrode 3a connected to the second common electrode 3b.

The second common electrode 3b is formed on the incidence surface of the seat 5 so as to cover at least a portion of the seat 5 and the second common electrode 3b is connected to the first common electrode 3a. Thus, the second common electrode 3b is bent at the periphery of the semiconductor 2 and the seat 5, and a bent portion thereof is formed sharp. The first common electrode 3a formed along the incidence surface of the semiconductor 2 is disposed under the sharp portion of the second electrode 3b (i.e., opposite to the incidence surface). Consequently, the common electrode 3 seen from a bottom (opposite to the incidence surface) has a uniform shape, which avoids occurrence of irregular concentration of the electric fields. As a result, dark current due to concentration of the electric fields may be suppressed.

A glass substrate, for example, is used for the active matrix substrate 1. The glass substrate for the active matrix substrate 1 has a thickness of approximately 0.5 mm to 1.5 mm, for example. The semiconductor 2 typically has a thickness of approximately 0.5 mm to 1.5 mm, and an area of approximately 20 cm to 50 cm long by 20 cm to 50 cm wide, for example. The seat suitably has a thickness in a range of 0.2 mm to 2.0 mm, for example. Within the range, there may be reduced the shock applied when the lead wire 4 is connected to the common electrode 3, which leads to improved conduction reliability of the common electrode 3 at the portion of the seat 5. The seat having a thickness of less than 0.2 mm is likely to be distorted due to the insufficient thickness thereof, which tends to be incapable of obtaining sufficient buffer functions. Conversely, the seat having a thickness of over 2.0 mm is likely to generate poor conduction due to step separation at the common electrode 3, which tends to reduce conduction reliability.

The radiation sensitive semiconductor 2 is preferably one of an amorphous semiconductor of high purity amorphous selenium (a-Se), selenium or selenium compound doped with an alkali metal such as Na, a halogen such as Cl, As or Te, and a non-selenium base polycrystalline semiconductor such as CdTe, CdZnTe, PbI₂, HgI₂ or TlBr. An amorphous semiconductor of amorphous selenium, selenium or selenium compound doped with an alkali metal, a halogen, As or Te, and a non-selenium base polycrystalline semiconductor, have excellent aptitude for large area and large film thickness. On the other hand, these have a Mohs hardness of 4 or less, and thus are flexible and likely to be damaged. However, the seat 5 may reduce the shock occurring when the lead wire 4 is connected to the common electrode 3, thereby protecting the semiconductor from damage. This facilitates formation of the semiconductor 2 with increased area and thickness. In particular, a-Se with a resistivity of 10⁹Ω or greater, preferably 10¹¹Ω or greater, has an outstanding aptitude for large area and large film thickness when used for the semiconductor 2.

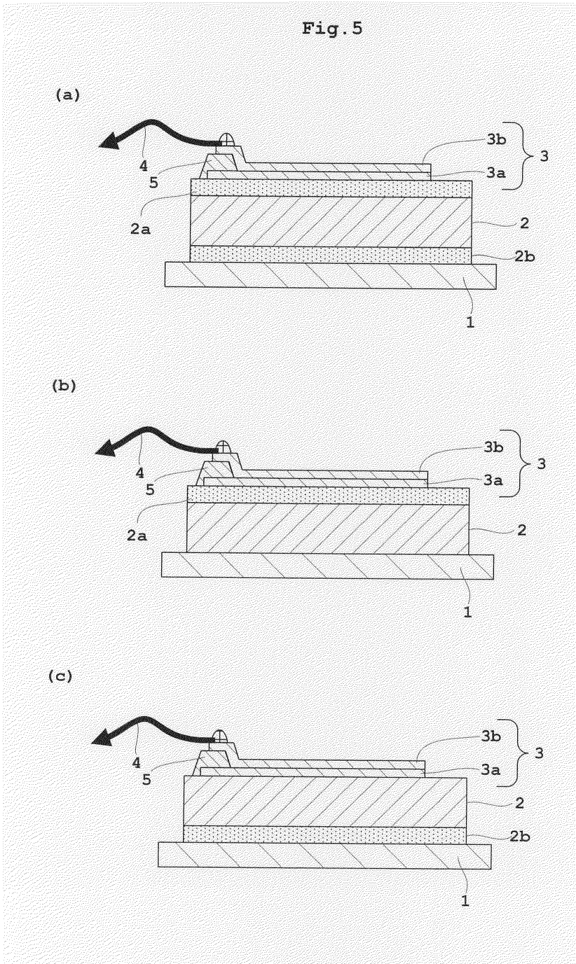

In addition to the sensitive semiconductor 2 described above, the semiconductor 2 may he combined with an intermediate layer, which is a carrier selective high-resistance semiconductor layer, formed on the incidence surface (upper surface in FIG. 2) or opposite surface to the incidence surface (lower surface in FIG. 2) or both surfaces. As shown in FIG. 5(a), an intermediate layer 2a may be formed between the semiconductor 2 and the first common electrode 3a, and an intermediate layer 2b may be formed between the semiconductor 2 and the collecting electrodes 11 (see FIG. 4). As shown in FIG. 5(b), the intermediate layer 2a may be formed only between the semiconductor 2 and the first common electrode 3a. As shown in FIG. 5(c), the intermediate layer 2b may be formed only between the semiconductor 2 and the collecting electrodes 11 (see FIG. 4).

With the carrier selective intermediate layers 2a and 2b disposed as above, dark current may be reduced. The carrier selectivity here refers to a property of being remarkably different in contribution to the charge transfer action between electrons and holes, which are charge transfer media (carriers) in a semiconductor.

The semiconductor 2 and the carrier selective intermediate layers 2a and 2b may be combined in the following modes. Where a positive bias voltage is to be applied to the common electrode 3, the intermediate layer 2a is formed of a material having a large contribution of electrons. This prevents injection of holes from the common electrode 3, thereby reducing dark current. The intermediate layer 2b is formed of a material having a large contribution of holes. This prevents injection of electrons from the collecting electrodes 11, thereby reducing dark current.

Conversely, were a negative bias voltage is applied to the common electrode 3, the intermediate layer 2a is formed of a material having a large contribution of holes. This prevents injection of electrons from the common electrode 3, thereby reducing dark current. The intermediate, layer 2b is formed of a material having. a large contribution of electrons. This prevents injection of holes from the collecting electrodes 11, thereby reducing dark current.

A preferred thickness of the carrier selective intermediate layers 2a and 2b is normally in a range of 0.1 μm to 10 μm. A thickness of the intermediate layers 2a and 2b less than 0.1 μm tends to be incapable of suppressing dark current sufficiently. Conversely; a thickness of over 10 μm tends to obstruct radiation detection (e.g. tends to reduce sensitivity).

Semiconductors to be used for the carrier selective intermediate layers 2a and 2b having an excellent aptitude for large area include polycrystalline semiconductors such as Sb₂S₃, ZnTe, CeO₂, CdS, ZnSe or ZnS, or amorphous semiconductors of selenium or selenium compound doped with an alkali metal such as Na, a halogen such as Cl, As or Te. These semiconductors are thin and likely to be damaged. However, the seat 5 may reduce the shock occurring when the lead wire 4 is connected to the common electrode 3, thereby protecting the intermediate layers from damage. This provides the carrier selective intermediate layers 2a and 2b with an excellent aptitude for large area.

Semiconductors to be used for the intermediate layers 2a and 2b having a large contribution of electrons include polycrystalline semiconductors such as CeO₂, CdS, CdSe, ZnSe or ZnS, as n-type semiconductors, and amorphous materials such as amorphous selenium doped with an alkali metal, As or Te to reduce the contribution of holes.

Those having a large contribution of holes include polycrystalline semiconductors such as ZnTe, as p-type semiconductors, and amorphous materials such as amorphous selenium doped with a halogen to reduce the contribution of electrons.

Further, Sb₂S₃, CdTe, CdZnTe, PbI₂, HgI₂, TlBr; non-doped amorphous selenium or selenium compounds include the type having a large contribution of electrons and the type having a large contribution of holes. In such case, either the type having a large contribution of electrons or the type having, a large contribution of holes may be selected for use as long as film forming conditions are adjusted.

The common electrode 3 is preferably formed, for example of gold (Au), aluminum (Al), etc. in Embodiment 1 and in Embodiments 2 to 4 to follow, both of the first common electrode 3a and the second common electrode 3b are formed of gold, and thus gold deposition is performed. Here, both of the first common electrode 3a and the second common electrode 3b may be formed of the same material. Moreover, for example, one of the common electrodes may be formed of gold, whereas the other of the common electrodes formed of aluminum. As mentioned above, two common electrodes 3a and 3b may be formed of materials different to each other.

Further, the insulating seat 5 is preferably formed of a hard resin material such as epoxy resin, polyurethane resin, or acrylic resin. The seat 5 formed of a hard resin material (curable to a high degree of hardness), such as epoxy resin, polyurethane resin or acrylic resin, does not easily expand or contract, and has an excellent buffer function, compared to one formed of a flexible material such as silicone resin or synthetic rubber. Thus, the seat 5 can fully reduce the shock occurring when the lead wire 4 is connected to the common electrode 3.

### EMBODIMENT 2

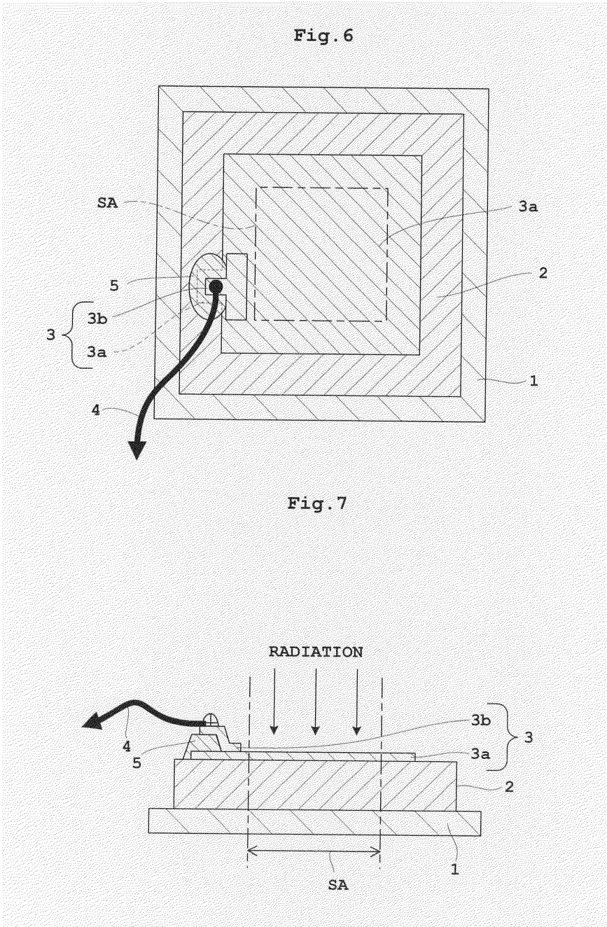

Embodiment 2 of this invention will be described in detail hereinafter with reference to the drawings. FIG. 6 is a schematic plan view of a flat-panel X-ray detector (FPD) in accordance with Embodiment 2. FIG. 7 is a schematic sectional view of the flat-panel X-ray detector (FPD) in accordance with Embodiment 2. Parts identical to those in the above Embodiment 1 will be designated with the same reference numbers. Here, the description as well as the illustration thereof will be omitted.

As shown in FIG. 1 and FIG. 2, the FPD according to the foregoing Embodiment 1 has the first common electrode 3a and the second common electrode 3b both having a dimension in a predetermined range including the radiation detection effective area SA. On the other band, in the FPD according to Embodiment 2, as shown in FIG. 6 and FIG. 7, only the first common electrode 3a has a dimension in a predetermined range including the radiation detection effective area SA, and the second common electrode 3b is disposed on a portion on the seat 5 outside the radiation detection effective area SA.

The first common electrode 3a is sufficiently connected to the second common electrode 3b on the seat 5 and the perimeter thereof. Thus, as in Embodiment 2, the second common electrode 3b may be disposed only on the portion on the seat 5 outside the radiation detection effective area SA. The second common electrode 3b has a smaller area compared to that in Embodiment 1. As a result, the second common electrode 3b may be formed (for example, vapor deposited) only on the seat 5 and the corresponding perimeter thereof, which allows reduction of an amount of the material to be used for formation (for example, deposition) of the second common electrode 3b. Moreover, there may be generally decreased influences of heat on the semiconductor 2 occurring from the formation (for example, the vapor deposition).

### EMBODIMENT 3

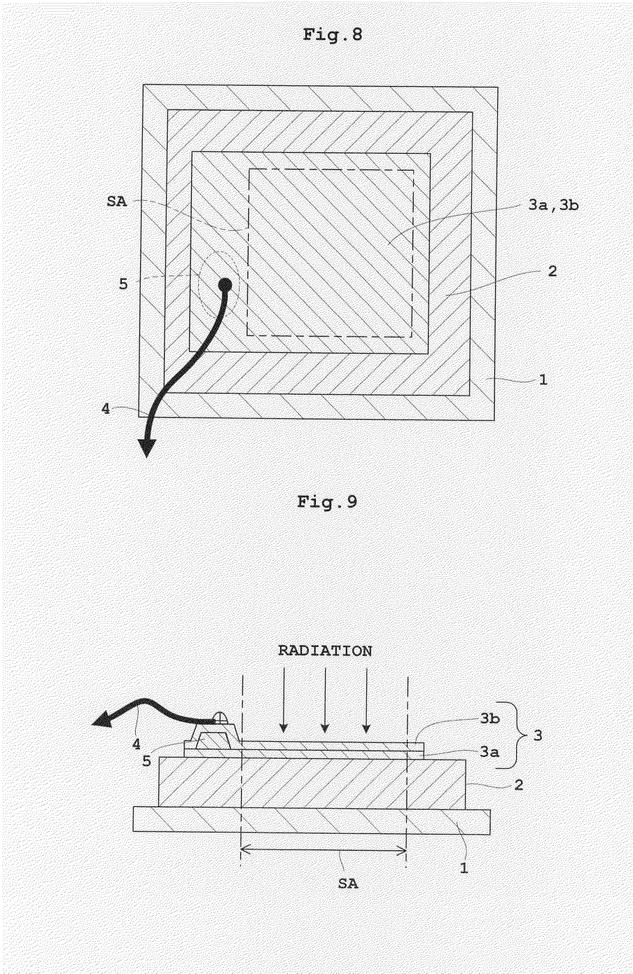

Embodiment 3 of the invention will he described in detail hereinafter with reference to the drawings. FIG. 8 is a schematic plan view of a flat-panel X-ray detector (FPD) in accordance with Embodiment 3. FIG. 9 is a schematic sectional view of the fiat-panel X-ray detector (FPD) in accordance with Embodiment 3. Parts identical to those in the above Embodiments 1 and 2 will be designated by the same reference numbers, and the description as well as the illustration thereof will be omitted.

As shown in FIG. 1 and FIG. 2, the FPD according to foregoing Embodiments 1 and 2 has the second common electrode 3b formed on the incidence surface of the seat 5 so as to cover a portion of the seat 5. On the other hand, as shown in FIG. 8 and FIG. 9, the FPD according to Embodiment 3 has the second common electrode 3b formed so as to cover the entire seat 5. As mentioned above, the second common electrode 3b may be formed on the incidence surface of the seat 5 so as to cover a portion of the seat 5 as in Embodiments 1 and 2. The second common electrode 3b may also be formed on the incidence surface of the seat 5 so as to cover the entire seat 5 as in Embodiment 3. Thus, the FPD is not particularly limited as long as the second common electrode 3b is formed on the incidence surface of the seat 5 so as to cover at least a portion of the seat 5.

### EMBODIMENT 4

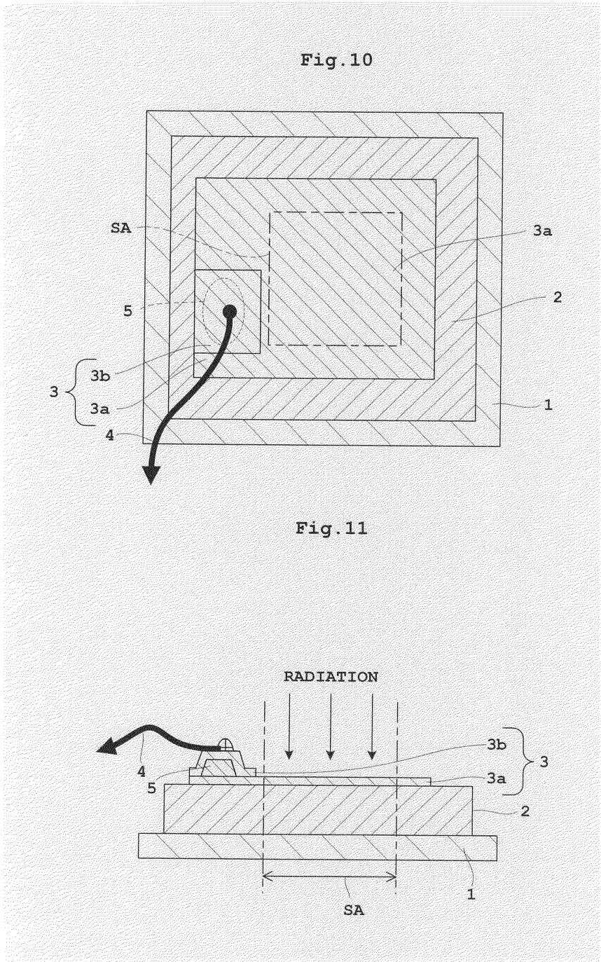

Embodiment 4 of this invention will be described in detail hereinafter with reference to the drawings. FIG. 10 is a schematic plan view of a flat-panel X-ray detector (FPD) in accordance with Embodiment 4. FIG. 11 is a schematic sectional view of the flat-panel X-ray detector (FPD) in accordance with Embodiment 4. Parts identical to those in the above Embodiments 1 to 3 will be designated by the same reference numbers, and the description as well as the illustration thereof will be omitted.

The FPD according to the foregoing. Embodiments 1 and 3 has the first common electrode 3a and the second common electrode 3b both having a dimension in a predetermined range including, the radiation detection effective area SA. On the other hand, in the FPD according to Embodiment 4 as shown in FIG. 10 and FIG. 11, only the first common electrode 3a has a dimension in a predetermined range including the radiation detection effective area SA, and the second common electrode 3b is disposed on a portion on the seat 5 outside the radiation detection effective area SA, which is similar to Embodiment 2.

Moreover, the FPD according to the above Embodiments 1 and 2 has the second common electrode 3b formed so as to cover a portion of the seat 5, whereas the FPD according to the above Embodiment 4 as shown in FIG. 10 and FIG. 11 has the second common electrode 3b so as to cover the entire seat 5, which is similar to Embodiment 3. In other words, the FPD according to Embodiment 4 has a configuration of combination of the FPD according to Embodiment 2 and that according to Embodiment 3.

This invention is not limited to the foregoing embodiments, but may be modified as follows:

(1) The radiation detector, as typified by a flat panel X-ray detector, described in each of the above embodiment is a type of two-dimensional array. The radiation detector according to this invention may be a type of one-dimensional array having collecting electrodes formed in a one-dimensional matrix may, or a type of non-array having a single electrode for fetching radiation detection signals.

(2) In each of the above embodiment, the radiation detector is described taking an X-ray detector as an example. However, this invention may be applied to radiation detectors (e.g. gamma ray detectors) for detecting radiation other than X-rays (e.g. gamma rays).

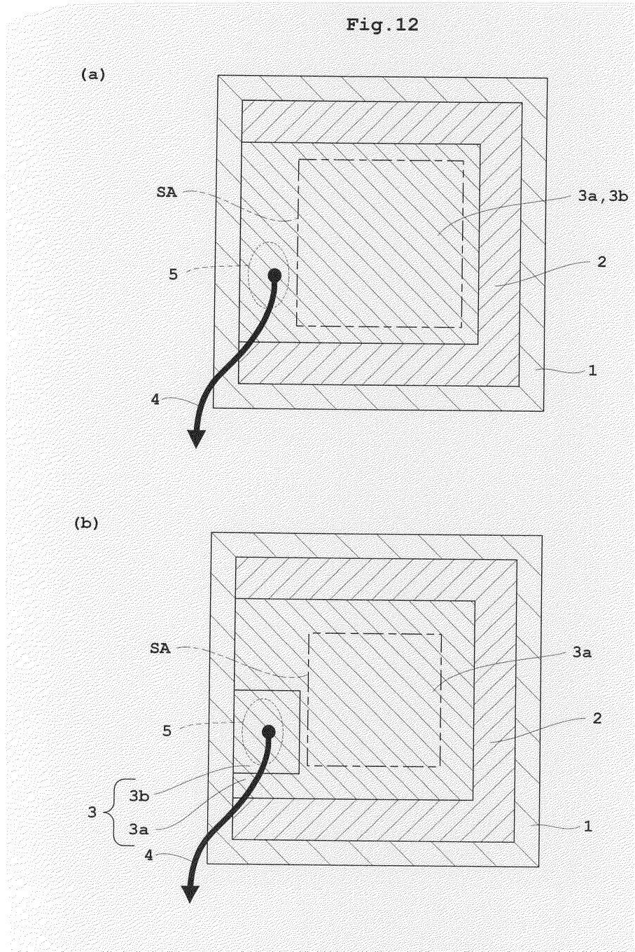

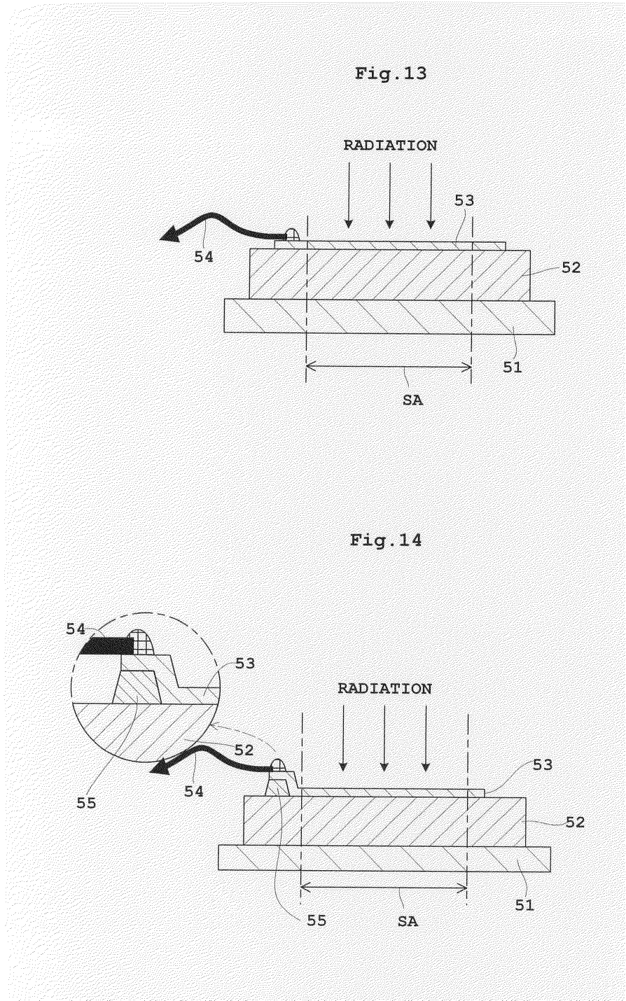

(3) In each of the above embodiments, the common electrode 3 is formed inwardly from the semiconductor 2 in order to prevent creeping discharge. With no consideration of creeping discharge, the edges of the common electrode 3 and the semiconductor 2 may be kept aligned, or the common electrode 3 may be formed outwardly from the semiconductor 2. The configuration shown in FIG. 12(a) may be made, for example, in combination of the configuration of Embodiment 3 shown in FIG. 8 and the configuration in which the edges of the common electrode 3 and the semiconductor 2 are kept aligned. In addition, the configuration shown in FIG. 12(b) may be made, for example, in combination of the configuration of Embodiment 4 shown in FIG. 10 and the configuration in which the edges of the common electrode 3 and the semiconductor 2 are kept aligned. Of course, the combination may be made of the configuration Embodiment 1 or 2 and the configuration in which the edges of the common electrode 3 and the semiconductor 2 are kept aligned. Moreover, the right or upper or lower edges of the common electrode 3 and the semiconductor 2 in the figure ma be kept aligned. In the configuration in which the common electrode 3 is formed outwardly from the semiconductor 2, combination will be made of the configurations of each embodiment.

1. A radiation detector for detecting radiation, comprising a radiation sensitive semiconductor for generating electric charges upon incidence of the radiation, a first common electrode for bias voltage application planarly formed so as to directly contact an incidence surface of the semiconductor, an insulating seat formed on an incidence surface of the first common electrode so as to cover a portion of the first common electrode, a second common electrode for bias voltage application formed on an incidence surface of the seat so as to cover at least a portion of the seat and connected to the first common electrode, and a lead wire for bias voltage supply connected to a portion of the incidence surface of the second electrode located on the seat, wherein the first common electrode has a dimension in a predetermined range including a radiation detection effective area.

2. The radiation detector according to claim 1, wherein the second common electrode also has a dimension in a predetermined range including the radiation detection effective area.

3. The radiation detector according to claim 1, wherein the second common electrode is disposed on a portion on the seat outside the radiation detection effective area.

4. The radiation detector according to claim 1, wherein the second common electrode is formed so as to cover the entire seat.

5. The radiation detector according to claim 4, wherein the second common electrode also has a dimension in a predetermined range including the radiation detection effective area.

6. The radiation detector according to claim 4, wherein the second common electrode is disposed on a portion on the seat outside the radiation detection effective area.

7. The radiation detector according to claim 1, comprising collecting electrodes for collecting the electric charges, wherein a carrier selective intermediate layer is formed between the semiconductor and the first common electrode, and a carrier selective intermediate layer is formed between the semiconductor and the collecting electrodes.

8. The radiation detector according to claim 1, wherein the intermediate layer is formed only between the semiconductor and the first common electrode.

9. The radiation detector according to claim 1, comprising collecting electrodes for collecting the electric charges, wherein the intermediate layer is formed only between the semiconductor and the collecting electrodes.

10. The radiation detector according to claim 1, wherein the detector is a type of two-dimensional array having the collecting electrodes for collecting the electric charges formed in a two-dimensional matrix array.

11. The radiation detector according to claim 1, wherein the detector is a type of one-dimensional array having the collecting electrodes for collecting the electric charges formed in a one-dimensional matrix array.

12. The radiation detector according to claim 1, wherein the radiation is X-rays.
